(19) United States
(12) Patent Application Publication
(10) Pub. No.: US 2011/0005586 A1
(43) Pub. Date: Jan. 13, 2011

(54) Electrochemical Deposition Methods for Fabricating Group IBIIIAVIA Compound Absorber Based Solar Cells

(75) Inventors: Serdar AKSU, Santa Clara, CA (US); Jiaxiong WANG, Castro Valley, CA (US); Bulent M. BASOL, Manhattan Beach, CA (US)

Correspondence Address: PILLSBURY WINTHROP SHAW PITTMAN LLP, P.O. BOX 10500, MCLEAN, VA, 22102, US

(73) Assignee: SoloPower, Inc., San Jose, CA (US)

(21) Appl. No.: 12/501,371

(22) Filed: Jul. 10, 2009

(51) Int. Cl. H01L 31/0216; C25D 7/12

(52) U.S. Cl. 136/256; 205/157

(57) ABSTRACT

A method of forming a Group IBIIIAVIA absorber layer on a base for manufacturing a solar cell is provided. The method, in one embodiment, includes forming a precursor stack by electroplating a first metallic layer on the base. The first metallic layer includes at least one of copper, indium and gallium. A first selenium layer is deposited on the first metallic layer, and an interlayer is electrodeposited on the selenium layer. The interlayer includes one of gold and silver. A second metallic layer is electrodeposited on the interlayer, the second metallic layer comprising at least one of copper indium and gallium. The interlayer inhibits dissolution of selenium during the electrodeposition of the second metallic layer. Such prepared precursor stack is reacted at a temperature range of 300-600° C. to form the Group IBIIIAVIA absorber layer.

### BACKGROUND

1. Field of the Inventions

The present inventions generally relate to electroplating methods and, more particularly, to techniques to form Group IBIIIAVIA compound absorber layers for thin film solar cells.

2. Description of the Related Art

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce the cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA compound semiconductors including some of the Group IB (Cu, Ag, Au), Group IIIA (B, Al, Ga, In, Tl) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ(S_{y}Se_{1-y})ₖ, where 0≦x≦1, 0≦y≦1 and k is approximately 2, have already been employed in solar cell structures that yielded conversion efficiencies approaching 20%. Absorbers containing Group IIIA element Al and/or Group VIA element Te also showed promise. Therefore, in summary, compounds containing: i) Cu from Group IB, ii) at least one of In, Ga, and Al from Group IIIA, and iii) at least one of S, Se, and Te from Group VIA, are of great interest for solar cell applications. It should be noted that although the chemical formula for CIGS(S) is often written as Cu(In,Ga)(S,Se)₂, a more accurate formula for the compound is Cu(In,Ga)(S,Se)ₖ, where k is typically close to 2 but may not be exactly 2. For simplicity we will continue to use the value of k as 2. It should be further noted that the notation “Cu(X,Y)” in the chemical formula means all chemical compositions of X and Y from (X=0% and Y=100%) to (X=100% and Y=0%). For example, Cu(In,Ga) means all compositions from Cuin to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1.

The structure of a conventional Group IBIIIAVIA compound photovoltaic cell such as a Cu(In,Ga,Al)(S,Se,Te)₂ thin film solar cell is shown in FIG. 1. A photovoltaic cell 10 is fabricated on a substrate 11, such as a sheet of glass, a sheet of metal, an insulating foil or web, or a conductive foil or web. An absorber film 12, which includes a material in the family of Cu(In,Ga,Al)(S,Se,Te)₂ is grown over a conductive layer 13 or contact layer, which is previously deposited on the substrate 11 and which acts as the electrical contact to the device. The substrate 11 and the conductive layer 13 form a base 20 on which the absorber film 12 is formed. Various conductive layers including Mo, Ta, W, Ti, and their nitrides have been used in the solar cell structure of FIG. 1. If the substrate itself is a properly selected conductive material, it is possible not to use the conductive layer 13, since the substrate 11 may then be used as the ohmic contact to the device. After the absorber film 12 is grown, a transparent layer 14 such as a CdS, ZnO, CdS/ZnO or CdS/ZnO/ITO stack is formed on the absorber film 12. Radiation 15 enters the device through the transparent layer 14. Metallic grids (not shown) may also be deposited over the transparent layer 14 to reduce the effective series resistance of the device. The preferred electrical type of the absorber film 12 is p-type, and the preferred electrical type of the transparent layer 14 is n-type. However, an n-type absorber and a p-type window layer can also be utilized. The preferred device structure of FIG. 1 is called a “substrate-type” structure. A “superstrate-type” structure can also be constructed by depositing a transparent conductive layer on a transparent superstrate such as glass or transparent polymeric foil, and then depositing the Cu(In,Ga,Al)(S,Se,Te)₂ absorber film, and finally forming an ohmic contact to the device by a conductive layer. In this superstrate structure light enters the device from the transparent superstrate side.

The first technique that yielded high-quality Cu(In,Ga)Se₂ films for solar cell fabrication was co-evaporation of Cu, In, Ga and Se onto a heated substrate in a vacuum chamber. However, low materials utilization, high cost of equipment, difficulties faced in large area deposition and relatively low throughput are some of the challenges faced in commercialization of the co-evaporation approach. Another technique for growing Cu(In,Ga)(S,Se)₂ type compound thin films for solar cell applications is a two-stage process where metallic components of the Cu(In,Ga)(S,Se)₂ material are first deposited onto a substrate, and then reacted with S and/or Se in a high temperature annealing process. For example, for CuInSe₂ growth, thin layers of Cu and In are first deposited on a substrate and then this stacked precursor layer is reacted with Se at elevated temperature. If the reaction atmosphere also contains sulfur, then a CuIn(S,Se)₂ layer can be grown. Addition of Ga in the precursor layer, i.e. use of a stack such as a Cu/In/Ga stacked film precursor, allows the growth of a Cu(In,Ga)(S,Se)₂ absorber.

Sputtering and evaporation techniques have been used in prior art approaches to deposit the layers containing the Group IB and Group IIIA components of the precursor stacks. In the case of CuInSe₂ growth, for example, Cu and In layers are sequentially sputter-deposited on a substrate and then the stacked film is heated in the presence of gas containing Se at elevated temperature for times typically longer than about 30 minutes, as described in U.S. Pat. No. 4,798,660. More recently U.S. Pat. No. 6,048,442 disclosed a method including sputter-depositing a stacked precursor film including a Cu—Ga alloy layer and an In layer to form a Cu—Ga/In stack on a metallic back electrode layer and then reacting this precursor stack film with one of Se and S to form the absorber layer. U.S. Pat. No. 6,092,669 described sputtering-based equipment for producing such absorber layers.

Two-stage processing approach may also employ stacked layers having Group VIA materials. For example, a Cu(In,Ga)Se₂ or CIGS film may be obtained by depositing In—Ga-selenide and Cu-selenide layers in a stacked manner and reacting them in presence of Se. Similarly, stacks having Group VIA materials and metallic components may also be used. Selenium may be deposited on a metallic precursor film including Cu, In and/or Ga through various approaches to form stacks such as Cu/In/Ga/Se and Cu—Ga/In/Se. One approach for Se layer formation is evaporation as described by J. Palm et al. (“CIS module pilot processing applying concurrent rapid selenization and sulfurization of large area thin film precursors”, Thin Solid Films, vol. 431-432, p. 514, 2003) in their work that involved preparation of a Cu—Ga/In metallic precursor film by sputtering and evaporation of Se over the In surface to form a Cu—Ga/In/Se stack. After rapid thermal annealing and reaction with S, these researchers reported formation of Cu(In,Ga)(Se,S)₂ or CIGS(S) absorber layer.

Evaporation is a relatively high cost technique to employ in large scale manufacturing of absorbers intended for low cost solar cell fabrication. Potentially lower cost techniques such as electroplating have been reported for deposition of Se or Se containing films. Electroplating can be used for depositing substantially pure Se thin films as well as for co-depositing Se with Cu, In and Cu metallic components. One specific method for the former case involves depositing a metallic precursor including Cu and In on a substrate and then electroplating a Se layer over the Cu and In containing layer to form a Cu—In/Se stack. This stack may then be heated up to form a CuInSe₂ compound absorber. In the solar cell industry, there is a need for new methods to incorporate selenium to the precursor stacks for the fabrication of high efficiency thin film solar cells.

### SUMMARY

Provided in certain embodiments is a method for electroplating at least one of a copper film, an indium film and a gallium film over a selenium containing film having a thin layer of silver or gold on its surface. Also described are methods for electrodeposition of a variety of precursor structures including discrete Se layers or discrete Se-containing layers. Such precursor structures may be used for the formation of high quality CIGS type absorber layers, which, in turn may be used for the fabrication of high efficiency thin film solar cells.

### BRIEF DESCRIPTION OF THE DRAWINGS

FIG. 1 is a schematic view of a prior art solar cell structure;

FIG. 2 is a schematic view of a precursor stack of the prior art having a top selenium layer; and

FIGS. 3A and 3B are schematic views of precursor stacks including selenium layers located below metallic layers.

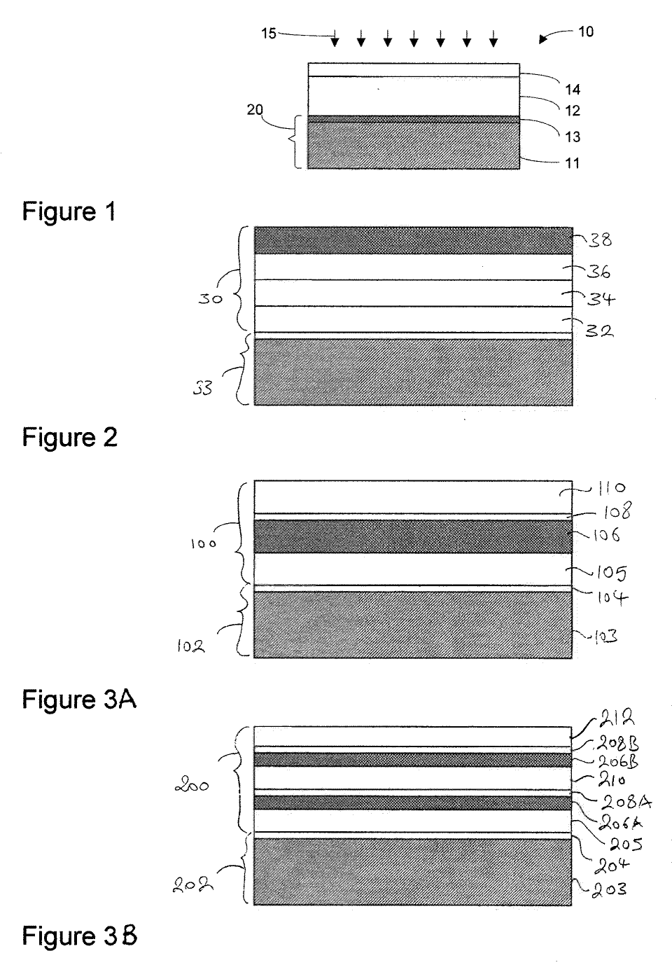

### DETAILED DESCRIPTION OF THE PREFERRED EMBODIMENTS

As described previously, copper-indium-gallium-selenide-(sulfide), or CIGS(S), and similar materials in the family of Group IBIIIAVIA semiconductors have emerged as important compounds for thin film polycrystalline solar cell applications. In a recently developed method for growth of CIGS(S) thin films, controlled amounts of Cu, In and Ga are electrodeposited in the form of stacks, such as Cu/In/Ga, Cu/Ga/In, In/Cu/Ga, Ga/In/Cu, Ga/Cu/In etc., on a base such as a substrate coated with a conductive contact layer. By electrodeposited, as is commonly understood and which is also referred to herein as electroplated, is meant that a current path is established within an electrolyte solution containing the metal to be plated (such as the Cu, In and Ga referred to above) between an anode (which may or may not contain the material to be plated) and the cathode that will be plated with the metal to be plated thereby forming a layer of the stack, with subsequent layers then being electrodeposited over previously electrodeposited layers.

These stacks are then reacted with Se and/or S vapors to form the CIGS(S) compound on the contact layer. Alternately, some of the Se and/or S can be also be provided on top of the precursor stack and this Se and/or S may be obtained through electrodeposition from an electrolyte. FIG. 2 shows an exemplary precursor stack 30 including a first metal layer 32 such as a Cu layer deposited on a base 33, a second metal layer 34 such as an In layer deposited on the first metal layer 32, a third metal layer 36 such as a Ga layer deposited on the second metal layer 34 and a selenium layer 38 deposited on top of the third metal layer to form a Cu/In/Ga/Se precursor stack. It is understood that S can be used in place of or in addition to the Se in selenium layer 38. By changing the order of metallic layers 32, 34 and 36, for example, various other electrodeposited stacks such as Cu/Ga/In/Se, In/Cu/Ga/Se, Ga/In/Cu/Se, and Ga/Cu/In/Se can be obtained, as well as similar stacks that have S or combinations of Se and S substituted for Se as noted. Such stacks can be reacted with additional Se and/or S to form a CIGS(S) compound layer or absorber layer on the contact layer.

One significant limitation in the preparation of the precursor stacks by electrodeposition is the fact that Se and/or S is only deposited as the very top layer. The reason for this is the difficulty of electrodepositing a metallic material on a Se film or a Se-rich film, and S film or on a S-rich film, which may be defined as a film comprising at least 50 atomic percent Se and/or S. For example, In and Ga cannot be electrodeposited directly over a Se layer without the dissolution of significant amount of Se into the In and Ga electrolytes during the plating process, causing cross contamination and loss of Se from the stack. Deposition of a Cu film over a Se layer by electrodeposition is also very restricted because it necessitates the use of acidic Cu plating solutions, which might cause corrosion problems. In addition, Cu plating in this case needs to be carried out at very low current densities to avoid dissolution of Se. Low current densities lower the throughput of the process and increase cost. In low pH solutions, on the other hand, there is risk of producing H₂Se gas, a highly toxic and poisonous gas, which can be generated on the cathode surface as a reduction product of Se dissolution during the electrodeposition process. These limitations have been restricting the preparation of stacks by low cost electrodeposition approaches in which the Se layer is buried below In containing, Ga containing or Cu containing layers. Having Se layer buried under metallic layers of the stack rather than having it on the top of the precursor stack has consequences for CIGS film formation. For example, when a Cu/In/Ga/Se stack, deposited on a base in that order, is subjected to high temperature, reaction starts at the top of the film and then continues towards the base. If, however, a Se/Cu/In/Ga stack could be formed by electrodeposition on a base, in that order, when this stack is subjected to high temperatures, the reaction would start near the base between Cu and Se and then move towards the exposed surface of the film. Such changes in the reaction kinetics and reaction pathways change the quality of the resulting CIGS layers in terms of its morphology, distribution of Ga through the layer and the electronic properties. Therefore, ability to distribute Se anywhere in the stack in an electrodeposition process has many benefits that could not be explored so far. The above considerations that have been stated for Se also apply to S as well as combinations of Se and S in a single layer as well.

The embodiments described herein provide methods to form electroplated precursor stacks, which include one or more layers of Se containing materials, preferably substantially pure selenium (Se) buried under other metallic films comprising at least one of Cu, In and Ga. These precursor stacks or layers may be used for manufacturing Group IBIIIAVIA solar cell absorbers. Specifically, a method is provided to electrodeposit metallic layers over a Se layer by first depositing an interlayer such as a noble metal interlayer on the Se layer and subsequently depositing the metallic layers over the interlayer. As mentioned above, metallic layers such as Ga and In layers cannot be directly electroplated on a Se layer without dissolving a large portion of Se. This is believed to be due to the large negative cathodic potentials needed for the electrodeposition of In and Ga. Such large negative cathodic potentials are believed to dissolve Se by reducing it to H₂Se, HSe⁻ or Se²⁻ species. The present inventors discovered that the interlayer protects the underlying Se film and prevents its electrochemical dissolution during a subsequent electroplating process for the deposition of In containing and Ga containing thin films.

Selection of the interlayer material was found to be very important. Specifically, the interlayer material properties found important were: i) the interlayer material should preferably be able to coat the surface of a Se layer by electrodeposition, ii) the interlayer material should provide a good base for electrodeposition of another metal over it, the other metal comprising at least one of Cu, In and Ga, iii) the interlayer material needs to be able to protect the underlying Se layer from dissolution during the electrodeposition of the other layer comprising at least one of Cu, In and Ga, iv) since the interlayer material will become a part of the CIGS(S) absorber layer after the reaction step, it should be compatible with this semiconductor, i.e. it should not deteriorate the electronic and structural properties of the CIGS(S) absorber which will be used for solar cell fabrication.

Present inventors found that two metals, Ag and Au, satisfied the above conditions, Ag being the preferable metal. Experiments showed that during electrodeposition of an interlayer with at least 25 atomic percent of Ag and/or Au on Se, and preferably over 50 atomic percent of Ag and/or Au on Se, no appreciable electrochemical reduction of Se took place. Cu, In and Ga could be electroplated over Ag or Au interlayers without any problem. Large amounts of Ag (interlayer thicknesses as large as 300 nm, even larger) could be employed without negatively impacting the resulting CIGS(S) absorber film after the reaction. For Au, interlayer thicknesses as large as 100 nm may be used. Therefore, the embodiments described herein make it possible to incorporate distinct Se layers buried below the metallic layers of Cu, Ga and In. This way, a large process window and flexibility are provided for the placement of individual layers in the stack, which allows tailoring the optimal order of layers in the precursor stack to obtain solar cells with high conversion efficiencies.

FIG. 3A shows an examplary precursor stack 100 formed on a base 102 including a substrate 103 and a contact layer 104 formed on the substrate. In this embodiment, the stack 100 may include a first metallic layer 105 deposited over the contact layer 104, a Se layer 106 formed on the first metallic layer 105, an interlayer 108 deposited onto the Se layer 106 and a second metallic layer 110 electrodeposited onto the interlayer 108. Further in this embodiment, the first metallic layer 105 as well as the second metallic layer 110 may also comprise stacks of metallic films such as an In film, a Cu film and a Ga film. Alternately, either one of the first metallic layer 105 and the second metallic layer 110 may be metallic alloy films comprising at least two of Cu, In and Ga. In a preferred embodiment the first metallic layer 105 is electrodeposited. In another preferred embodiment both the first metallic layer 105 and the Se layer 106 are electrodeposited. If the first metallic layer 105 and the second metallic layer 110 comprise metallic films, such films may be electrodeposited in various orders. For example, the first metallic layer 105 may include a Cu film electrodeposited onto the contact layer, a Ga film electrodeposited onto the Cu film, and an In film electrodeposited onto the Ga film, i.e., a Cu/Ga/In film stack. The second metallic layer 110 may comprise an In—Ga alloy, or a stack of an In film and a Ga film. If Cu is included in the first metallic layer 105, it may or may not be included in the second metallic layer 110. In a preferred embodiment, the interlayer 108 comprises a thin Ag or Au film electrodeposited over the Se layer to enable subsequent electrodeposition of the second metallic layer 110 comprising at least one of Cu, In and Ga. In fact, such interlayer depositions may be multiple times if multiple selenium depositions are desired when forming a multilayer precursor stack. An exemplary interlayer thickness may be in the range of 5-500 nm, and preferably 10-100 nm.

FIG. 3B shows another exemplary precursor structure 200 formed on a base 202 including a substrate 203 and a contact layer 204 formed on the substrate. In this embodiment, the precursor stack 200 may include multiple interlayers; for example, a first interlayer 208A and a second interlayer 208B, deposited onto a first selenium layer 206A and a second selenium layer 206B respectively. The second precursor stack 200 is preferably constructed by electrodepositing various metallic layer, selenium layer and interlayer combinations as in the previous embodiment. Accordingly, the first selenium layer 206A is deposited, preferably electrodeposited, on a first metallic layer 205 which is formed on the contact layer 204, preferably by electrodeposition. The first metallic layer 205 comprises at least one of Cu, In and Ga. A second metallic layer 210 is electrodeposited onto the first interlayer 208A. Next, the second Se layer 206B is formed preferably by electrodeposition on the second metallic layer 210, and the second interlayer 208B is formed, preferably by electrodeposition on the second Se layer 206B. A third metallic layer 212 may consequently be electrodeposited onto the second interlayer 208B. As in the previous embodiment, in this embodiment, the metallic layers 205, 210 and 212 each may comprise at least one of Cu, In and Ga. They may also comprise various stacks of metallic films including one or more of In, Ga and Cu films deposited in various orders.

As explained through the examples given above, the embodiments provide the ability to place Se layer buried between two metallic layers where one metallic layer is electrodeposited over the Se layer. Using the Ag interlayer, for example, stacks such as Cu/In/Ga/Se/Ag/In, Cu/Ga/In/Se/Ag/Ga, In/Cu/Ga/Se/Ag/In/Se/Ag/Ga, Ga/In/Cu/Se/Ag/Ga, and many other possible combinations can be prepared. Any one of the Ag layers above may also be changed with Au. Such precursor stacks may be heated up to a temperature of 400-600° C., preferably in presence of additional Se and/or S to form “substrate/CuIn(Se,S)₂” or “substrate/Cu(In,Ga)(Se,S)₂” solar cell absorber structures as described before. Se thin films can be deposited using several different plating methods and plating solutions. A review of these techniques and an exemplary Se electrodeposition electrolyte is given in the U.S. patent application Ser. No. 12/121,687, entitled: Selenium Electroplating Chemistries and Methods, filed on May 14, 2008, which is assigned to the assignee of the presents application and which is incorporated herein in its entirety.

For the electrodeposition of Au and Ag films on Se there are several options with plating compositions and methods. Ag can be plated using both cyanide-based and non-cyanide plating solutions. Cyanide-based Ag plating is conducted in alkaline solutions, which typically contain potassium silver cyanide as silver source, potassium cyanide for free cyanide and potassium carbonate to increase the solution conductivity. Several different plating formulations are also available for non-cyanide plating process. Depending on the compound type these solutions can be divided into three groups. These groups can be listed as (1) simple salts, e.g., nitrate, fluoborate, and fluosilicate; (2) inorganic complexes, e.g., iodide, thiocyanate, thiosulfate, pyrophosphate, and trimetaphosphate; and (3) organic complexes, e.g., succinimide, lactate, and thiourea. There is a wide range of pH's for these solutions. For example, iodide-based solutions operate in acidic regime; while solutions based on trimetaphosphate, thiosulfate, succinimide operate at the pH range of about 8-10.

Similar to Ag plating, Au can be plated out from both cyanide and non-cyanide electrolytes. Typically, Au plating can be carried out using cyanide-based plating baths in either acidic, neutral or alkaline Au cyanide solutions. Non-cyanide Au plating formulations are usually based on the use of gold sulfite. Alloy films of Au and Ag, such as Au—Cu, Ag—Cu alloys could also be used. In this case, different current densities can be applied to obtain various ratios of Cu to Au or Ag without observable dissolution of Se.

### EXAMPLE 1

Ag was plated onto the Se surfaces from a thiosulfate Ag plating bath containing 20-40 g/L of Ag thiosulfate, 200-500 g/L of sodium thiosulfate, and 40-60 g/L of sodium citrate. The pH value was adjusted to between 10 and 11. The electroplating of Ag was carried out using this solution with current densities ranging from 5 to 30 mA/cm². The preferable current density range was between 5 and 10 mA/cm². The temperature of the plating solution was from 20 to 45° C. Temperatures below 30° C. are preferred. No significant dissolution of Se was observed during the Ag plating. The resultant Ag film was smooth, shiny and covered the Se surface with a uniform thickness distribution. The cathodic current efficiencies of Ag plating onto the Se surfaces were close to 100%.

In and Ga were electroplated onto the Ag interlayers without significantly dissolving Se. The In plating was carried out at room temperature with current densities ranging from 5-30 mA/cm², preferably 10 mA/cm². The resultant In films were smooth and uniform. Ga layers were electroplated with current densities ranging from 10-50 mA/cm², preferably 30-40 mA/cm². The Ga films were also smooth and uniform. Instead of Ga or In, a Cu layer could also be easily plated on Ag using the same approach. Alternately various alloys comprising at least one of Cu, In and Ga could also be electroplated at high efficiency.

### EXAMPLE 2

Au films were plated onto the electrodeposited Se films to function as interlayers for subsequent In and Ga plating. The Au solution used in these experiments contained 0.1-0.3 M sodium aurosulfite with a pH of about 8.5. The Au plating was conducted at room temperature with current densities ranging from 5 to 40 mA/cm². A high current density generated more uniform films but lower the plating efficiencies. The films were shiny, uniform and smooth.

The Au plating solution described above could be modified to an Au—Cu alloy plating solution by adding 0.1 M CuSO₄ into the solution. Using this alloy solution high quality Au—Cu layers could be plated over Se. In this case, films with different Cu to Au ratios can be electroplated by changing the current density from 10 to 40 mA/cm². More Cu was plated onto the substrates at low current densities. In and Ga films were plated successfully on the Au or Au—Cu alloy interlayers with plating baths and methods described in Example 1. Resultant In and Ga films were of high quality and suitable for preparation of precursor stacks for Group IBIIIAVIA solar cells. Instead of Ga or In, a Cu layer can also be easily plated on Au and Au—Cu alloy films using the same approach. These results showed that the interlayers may comprise pure Ag or Au. But alternately they may comprise a Ag—Cu alloy, a Au—Cu alloy, a Au—Ag alloy or a Au—Ag—Cu alloy.

It should be noted that the Ag or Au containing interlayers of the embodiments described herein have additional benefits. Generally, when In or Ga is electrodeposited on most surfaces, a pattern of island structures is formed. In other words a discontinuous film is formed, especially if the film thickness is below 1 micrometer. When electrodeposited on an Au or Ag interlayer, however, such In or Ga films are smooth and continuous, yielding precursors with more uniform morphology and composition. Therefore, use of Au or Ag interlayer minimizes or eliminates defects observed in electrodeposited In and Ga layers. For example, when In or Ga is electrodeposited on a Cu surface, the resulting film may often be rough and discontinuous, i.e. it may have an island structure exhibiting poor coverage over the Cu layer. U.S. patent application Ser. No. 12/143,609, filed on Jun. 20, 2008, entitled: Electroplating Method for Continuous Thin Layers of Indium-Rich Materials, which is assigned to the same assignee, describes a method to improve such defective In films, and is expressly incorporated by reference herein. In this embodiment, since Au and Ag are Group IB elements like Cu, some of the Cu in the precursor stack may be replaced with Au or Ag to achieve a CIGS film with less defects. For example, instead of using a Cu/In/Ga or a Cu/Ga/In precursor stacks, a Cu/Ag/In/Ga or a Cu/Ag/Ga/In stack may be used, respectively. When Ga or In is electrodeposited on the Au or Ag films formed on Cu, the coverage of the Ga or In layers is improved; the roughness of the Ga or In layers is reduced and thereby smoother films are formed.

In addition to electrolytic deposition, Ag and Au containing interlayers of the described embodiments can also be prepared by electroless deposition methods. In electroless plating, instead of externally applied electrical power, a reducing agent is included in the plating chemistry to reduce Ag and Au ions to metallic Ag and Au, respectively.

Further, depositing of the various layers other than the metallic layer deposited over the interlayer can be performed by methods other than electroplating, including electroless plating as referred to above, as well as by physical vapor deposition and chemical vapor deposition approaches including evaporation and sputtering.

Although it is preferable to apply the interlayers of the embodiments described herein to enable electrodeposition of a metallic layer on a Se-rich film, it should be noted that the embodiments can also be used more generally to electrodeposit a metallic layer comprising at least one of Cu, In and Ga over a Se-containing layer while preventing loss of Se from the Se-containing layer. The Se-containing layer may, in this case, contain at least one of Cu, In and Ga in addition to Se. The Se-containing layer may be a layer of a selenide such as copper selenide (Cu—Se), indiumn selenide (In—Se), gallium selenide (Ga—Se), and a mixture or alloy of these selenides.

Although the present inventions are described with respect to certain preferred embodiments, modifications thereto will be apparent to those skilled in the art.

We claim:

1. A method of forming a Group IBIIIAVIA absorber layer on a base for manufacturing a solar cell, comprising:
forming a precursor stack on the base; wherein the step of forming the precursor stack comprises:
forming a first layer over the base, the first layer comprising selenium and optionally at least one of copper, indium and gallium,
depositing an interlayer on the first layer, the interlayer including at least 25 atomic percent of at least one of gold and silver, and
electrodepositing a second metallic layer on the interlayer, the second metallic layer comprising at least one of copper, indium and gallium; and
reacting the precursor stack to form the Group IBIIIAVIA absorber layer.

2. The method of claim 1 wherein the first layer is a first selenium rich layer containing at least 50 atomic percent selenium.

3. The method of claim 2 wherein the step of forming the precursor stack further includes a step of forming a first metallic layer on the base before the step of forming the first selenium rich layer, wherein the first metallic layer includes at least one of copper, indium and gallium.

4. The method of claim 3, wherein the step of depositing the interlayer is carried out by electrodeposition.

5. The method of claim 4, wherein the step of forming the first selenium rich layer is carried out by electrodeposition.

6. The method of claim 5, wherein the first selenium rich layer is a substantially pure selenium layer and wherein the step of forming the first metallic layer is carried out by electrodeposition.

7. The method of claim 6 wherein the step of reacting the precursor stack is performed at a temperature range of 300-600° C. to form the Group IBIIIAVIA absorber layer.

8. The method of claim 3, wherein the step of forming the first metallic layer is carried out by electrodeposition.

9. The method of claim 3 wherein the step of reacting the precursor stack is performed at a temperature range of 300-600° C. to form the Group IBIIIAVIA absorber layer.

10. The method of claim 3 wherein the step of forming the precursor stack further comprises the step of electrodepositing a second selenium rich layer on the second metallic layer.

11. The method of claim 10 wherein the step of forming the precursor stack further comprises the step of electrodepositing a second interlayer on the second selenium rich layer, the second interlayer including at least 25 atomic percent of at least one of gold and silver.

12. The method of claim 11 further comprising the step of electrodepositing a third metallic layer on the second interlayer, the third metallic layer comprising at least one of copper, indium, and gallium.

13. The method of claim 3 wherein the step of electrodepositing the second metallic layer on the interlayer comprises:
applying an electrodeposition solution onto the interlayer, wherein the electrodeposition solution including at least one of copper, indium and gallium; and
applying a cathodic potential to the interlayer to electrodeposit the at least one of copper, indium and gallium within the electrodeposition solution onto the interlayer, wherein the interlayer inhibits dissolution of the first selenium rich layer.

14. The method of claim 13, wherein the selenium rich layer is a substantially pure selenium layer.

15. The method according to claim 1 wherein the step of depositing the interlayer is carried out by electroless deposition.

16. A precursor structure formed on a base for manufacturing a Group IBIIIAVIA solar cell absorber, comprising:
a first metallic layer formed over the base;
a selenium containing layer formed on the first metallic layer, the selenium containing layer optionally including at least one of copper, indium and gallium;
an interlayer formed on the selenium containing layer, the interlayer including at least 25 atomic percent of at least one of gold and silver; and
a second metallic layer formed on the interlayer, the second metallic layer including at least one of gallium, indium and copper.

17. The precursor structure of claim 16 wherein the first metallic layer includes at least one of indium, gallium and copper.

18. The precursor structure of claim 17 wherein the selenium containing layer is a selenium rich layer containing at least 50 atomic percent selenium.

19. The precursor structure of claim 18, wherein the interlayer has a thickness of 5-500 nm.

20. The precursor structure of claim 19, wherein the selenium rich layer has a thickness of 500-5000 nm.

21. The precursor structure of claim 19 wherein the selenium rich layer is a substantially pure selenium layer.

22. The precursor structure of claim 21 wherein the first metallic layer includes at least one of a Cu film, an indium film and a gallium film.

23. The precursor structure of claim 22 wherein the second metallic layer includes at least one of a copper film, an indium film and a gallium film.
